(19) United States
(12) Patent Application Publication
(10) Pub. No.: US 2006/0180934 A1
(43) Pub. Date: Aug. 17, 2006

(54) Wiring structures for semiconductor devices

(75) Inventors: Chung-Shi Liu, Hsinchu City (TW); Chen-Hua Yu, Keelung City (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/056,193

(22) Filed: Feb. 14, 2005

(51) Int. Cl. H01L 23/48

(52) U.S. Cl. 257/760; 257/E21.627

(57) ABSTRACT

Wiring structures of semiconductor devices and fabrication methods thereof. A metal layer electrically connected to at least one vertical connection formed in an insulating layer is provided. A dummy dielectric layer is formed in a portion of the metal layer. The dummy dielectric layer is located in a region adjacent to the vertical connection.

### BACKGROUND

The invention relates to semiconductor devices and fabrication methods thereof, and more particularly to wiring structures of semiconductor devices and fabrication methods thereof.

In the fabrication of ultra-large scale-integration (ULSI) circuit devices, vertical stacking, or integration, of metal wiring circuits, or metal layers, to form multilevel interconnection has become an efficient way to increase device performance and the functional complexity of devices. Electrical connections between adjacent metal layers are achieved by one or more vias (or holes) that are formed through the sandwiched insulating layer and connect two adjacent metal layers.

Typically, the semiconductor devices comprise wider metal lines and very fine vias. Due to the large difference in physical contacts such as the thermal expansion coefficients between the metal layer and the insulator, stress migration often occurs when the device is subjected to a rapid temperature ramp rate, up or down. This stress migration causes some problems. FIG. 1 is a sectional diagram depicting a conventional wiring structure 10 exhibiting a connection failure under a stress migration due to rapid temperature changes. The stress migration causes phenomena 11 wherein an upper metal layer 12 is lifted in the via 14 connected to a lower metal layer 16. Reference numeral 18 denotes an intermetal dielectric layer interposed between the two metal layers 12 and 16. Additionally, mobile metal atoms or defects caused by the stress migration may be pushed into the vias, resulting in circuit failure.

U.S. Pat. No. 5,407,863 to Katsura et al., the entirety of which is hereby incorporated by reference, discloses a method of manufacturing a semiconductor device comprising Al wirings providing high stress migration resistance. An aluminum film is deposited on a semiconductor substrate. The aluminum film is formed stepwise by stepwise changing the heating temperature of the semiconductor substrate at at least two stages.

U.S. Pat. No. 6,307,268 to Lin, the entirety of which is hereby incorporated by reference, discloses an interconnect structure for use in semiconductor devices. The interconnect structure eliminates the problems caused by stress migration by adding a plurality of regularly spaced dummy refractory plugs. The dummy refractory plugs serve as an atom reservoir to prevent the flow of mobile aluminum atoms into the via hole causing via failure.

U.S. Publication No. 2003/0116852 to Watanabe et al., the entirety of which is hereby incorporated by reference, discloses a semiconductor device. The semiconductor device eliminates the problems caused by stress migration by forming dummy plugs in an insulating film. The dummy plugs are provided in a non-forming region of a wiring and then the dummy plugs are connected to a dummy wiring, thereby improving stress migration resistance and mechanical strength of the wiring.

Wiring structures of semiconductor devices and fabrication methods thereof are provided. An exemplary embodiment of a wiring structure of a semiconductor device comprising a conductive layer electrically connected to at least one vertical connection formed in an insulating layer is provided. A dummy dielectric layer is formed in a portion of the conductive layer. The dummy dielectric layer is located in a region adjacent to (near or around) the vertical connection.

A dummy dielectric layer is formed in a portion of the conductive layer, wherein the dummy dielectric layer is located in a region adjacent to (near or around) the vertical connection. The dummy dielectric layer can thus prevent mobile metal atoms and/or defects generated through stress migration from moving into the vertical connection when the wiring structure is subjected to a rapid temperature change, thereby improving reliability.

Further scope of applicability of embodiments of the disclosure will become apparent from the detailed description given hereinafter. It should be understood that the detailed description and specific examples are given by way of illustration only, since various changes and modifications within the spirit and scope of the disclosure will become apparent to those skilled in the art from this detailed description.

### DESCRIPTION OF THE DRAWINGS

Wiring structures for semiconductor devices can be more fully understood by reading the subsequent detailed description in conjunction with the examples and references made to the accompanying drawings, wherein

FIG. 1 is a sectional view illustrating a conventional wiring structure exhibiting a connection failure under a stress migration due to rapid temperature changes;

FIG. 2 is a partial top view showing a plan layout of a first embodiment of a wiring structure;

FIGS. 3A-3C are sectional views illustrating an exemplary method of forming the wiring structure showing in FIG. 2;

FIGS. 4A-4D are sectional views illustrating another exemplary method of forming the wiring structure showing in FIG. 2;

FIG. 5 is a partial top view showing a plan layout of a second embodiment of a wiring structure; and

FIG. 6 is a partial top view showing a plan layout of a third embodiment of a wiring structure.

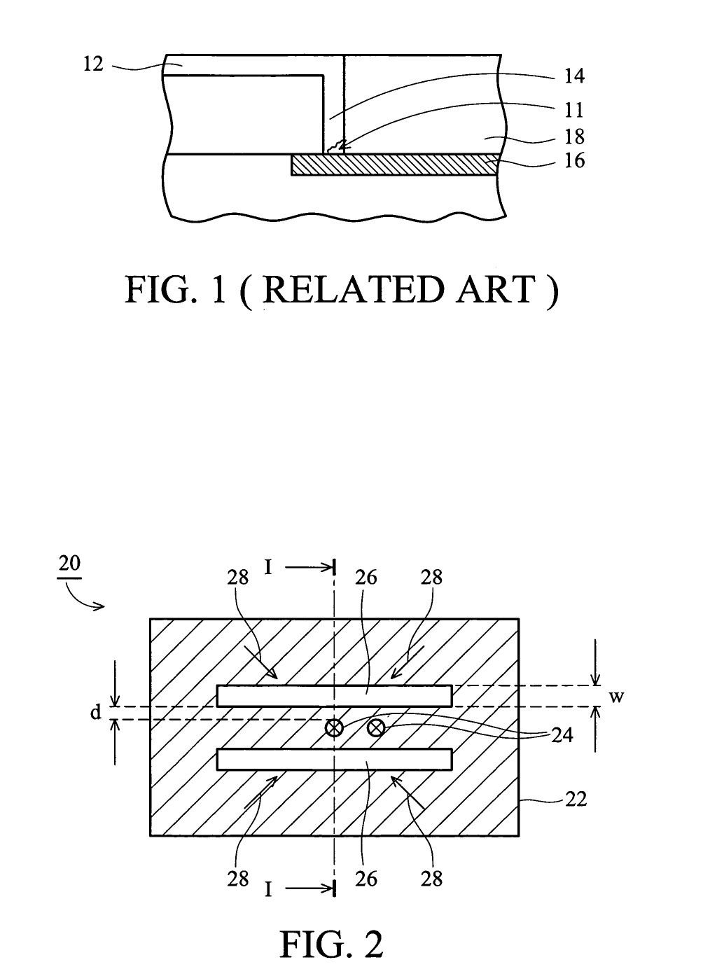

### DETAILED DESCRIPTION

### First Embodiment

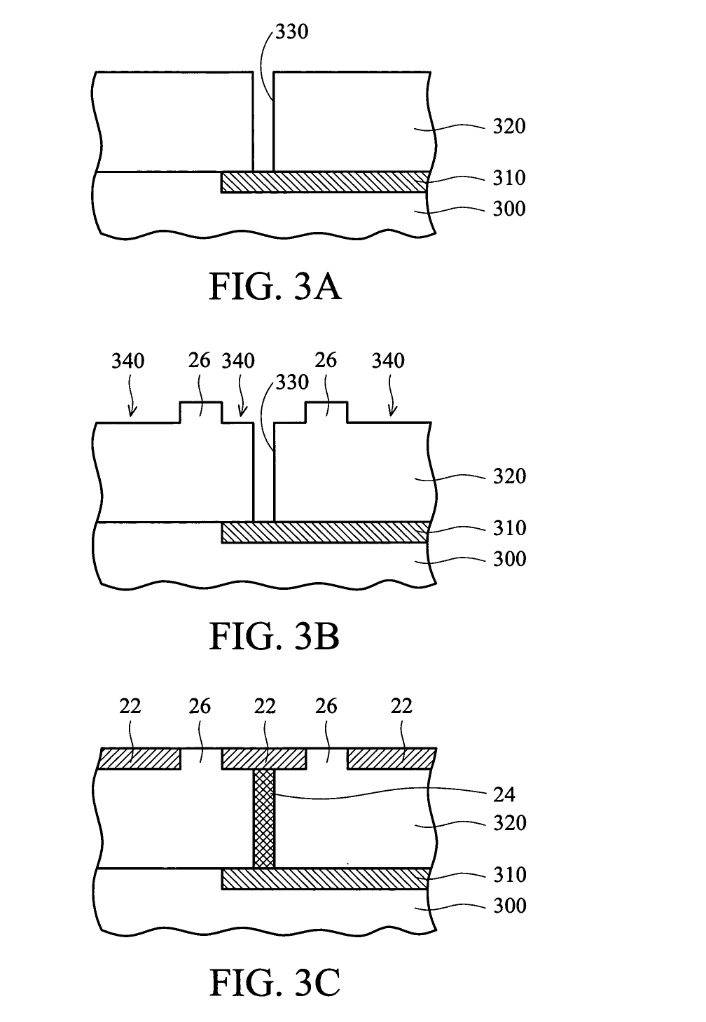

Wiring structures are provided. A partial plan layout of the first embodiment of a wiring structure is shown in FIG. 2. FIGS. 3A-3C are sectional views illustrating an exemplary method of forming the wiring structure, taken along a I-I line in FIG. 2. A representative dual-damascene process is illustrated in this embodiment, but is not intended to limit the disclosure. For convenience, a single level of interconnection is shown in the drawings, although there may be numerous levels.

In FIG. 3A, an underlying layer 300 is provided. The underlying layer 300 comprises a structure in which, for example, a MOSFET is formed in an active region of a silicon wafer (semiconductor substrate), then an insulating layer is formed on the surface of the wafer, and then wiring 310 is buried in the insulating layer. The wiring 310 may be an interconnect line comprising metal or other conductive material.

An intermetal dielectric (IMD) layer 320 covering the wiring 310 is then formed on the underlying layer 300. The IMD layer 320 is an insulating layer preferably comprising low-k dielectric material. The low-k dielectric material can be SiOC, SOG (spin on glass), FSG (fluorinated silica glass), HSQ (hydrogensilsequioxane) or the like. The IMD layer 320 can be deposited by CVD (chemical vapor deposition) to a thickness between about 2000 and 13000 Å. A first patterning procedure then forms at least one through hole (or via) 330 in the IMD layer 320 to expose the wiring 310.

In FIGS. 2 and 3B, a second patterning procedure forms a wiring trench 340 in the IMD layer 320; meanwhile, a dummy dielectric layer 26 remains on the top of the IMD layer 320. The dummy dielectric layer 26 is located in the wiring trench 340 and a region near or around the through hole 330. Note that two patterning procedures are employed in this case, but are not intended to limit the disclosure.

A barrier conductive layer (not shown) can be formed on inner walls of the through hole 330 and the wiring trench 340. The barrier conductive layer can comprise refractory metal such as titanium, tantalum, etc. A conductive material then fills the through hole 330 and the wiring trench 340 to form at least one vertical connection 24 and a conductive layer 22. The vertical connection 24 can comprise a via structure and/or plug. The conductive material comprises, for example, copper, aluminum or tungsten. CMP (chemical mechanical polishing) then planarizes the surface, creating smooth topography for the conductive layer 22, as shown as FIGS. 2 and 3C. The conductive layer 22 can serve as an interconnect line. The first embodiment of the wiring structure 20 is thus obtained.

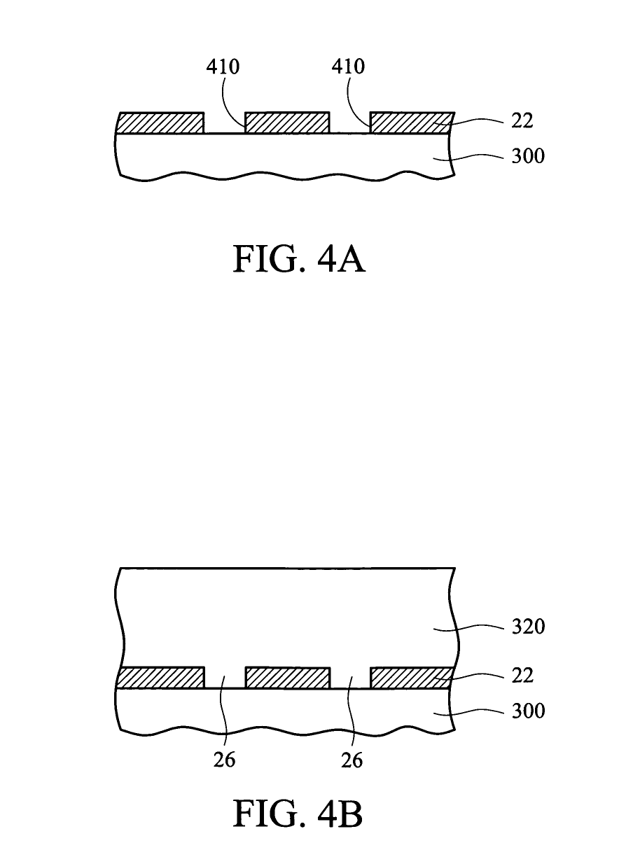

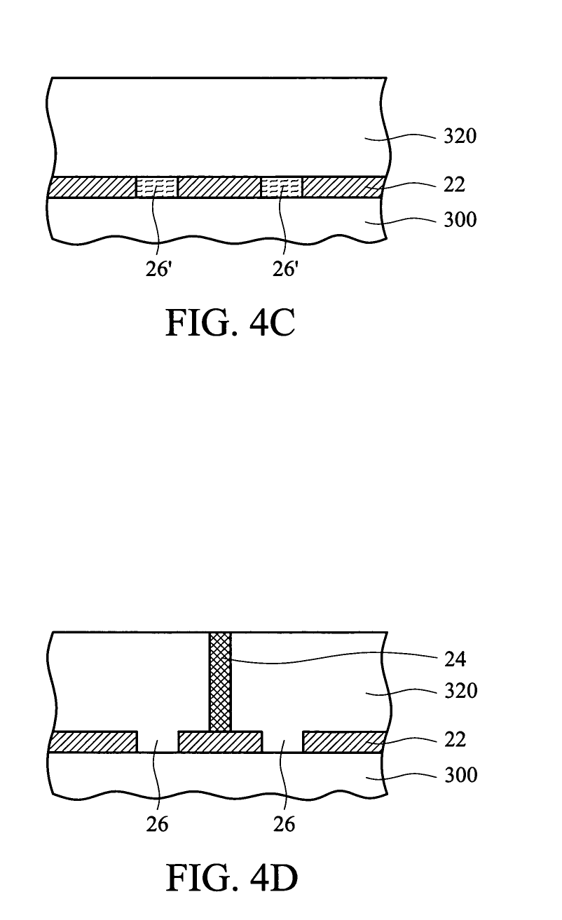

FIGS. 4A-4D are sectional views illustrating another exemplary method of forming the wiring structure 20, taken along a I-I line in FIG. 2. A representative single-damascene process is illustrated in this embodiment, but is not intended to limit the disclosure. For convenience, a single level of interconnection is shown in the drawings, although there may be numerous levels.

In FIGS. 2 and 4A, a conductive layer 22 comprising at least one opening 410 is defined on an underlying layer 300. The conductive layer 22 may be an interconnect line formed by patterning. The conductive layer 22 comprises, for example, copper, aluminum or tungsten. The opening 410 can expose the underlying layer 300.

In FIGS. 2 and 4B, an IMD layer 320 covering the conductive layer 22 is then formed on the underlying layer 300. Note that the IMD layer 320 also fills the opening 410 to form at least one dummy dielectric layer 26. Alternatively, referring to FIG. 4C, at least one dummy dielectric layer 26′ can fill the opening 410 before forming the IMD layer 320. That is, the dummy dielectric layer 26′ and the IMD layer 320 may or may not the same material.

In FIGS. 2 and 4D, at least one vertical connection 24 electrically connected to the metal layer 22 is formed in the IMD layer 320 by patterning and deposition. The vertical connection 24 comprises, for example, W, Cu, Al, Mo, Ti, Ta or a conductive metal compound. For some connection materials, it may be desirable to first deposit a liner (not shown) in order to avoid peeling (e.g., for a tungsten connection, a TiN, TiW or TiWN liner can be deposited to surround the tungsten in the through hole in the IMD layer). The vertical connection 24 can comprise a via structure and/or plug. Note that the dummy dielectric layer 26/26′ is located in a portion of the conductive layer 22 and a region near or around the vertical connection 24. The wiring structure 20 is thus obtained.

The wiring structure 20 can be applicable to a semiconductor device. Referring to FIG. 2, the wiring structure 20 comprises a conductive layer 22 electrically connected to at least one vertical connection 24 formed in an insulating layer. A dummy dielectric layer 26 is disposed in a portion of the conductive layer 22. The dummy dielectric layer 26 is located in a region near or around the vertical connection 24 to prevent mobile metal atoms and/or defects, shown by arrows 28, generated through stress migration from moving into the vertical connection 24 when the wiring structure 20 is subjected to a rapid temperature change.

In the wiring structure 20, the dummy dielectric layer 26 comprises two parallel segments and the vertical connection 24 corresponds to a region between the two parallel segments. Size conditions of this embodiment are illustrated, but are not intended to limit the disclosure. The conductive layer 22 has a width greater than 2 μm. The diameter of the vertical connection 24 is about 0.13 μm. The width “w” of the dummy dielectric layer 26 is between about 0.5 μm and 10 μm. The spacing “d” between the vertical connection 24 and the dummy dielectric layer 26 is between about 0 μm and 2 μm. However, the optimum spacing “d” depends on the width of the conductive layer, the type of conductive material used, the kind of thermal process involved, and the layout and density of the conductive layer.

### Second Embodiment

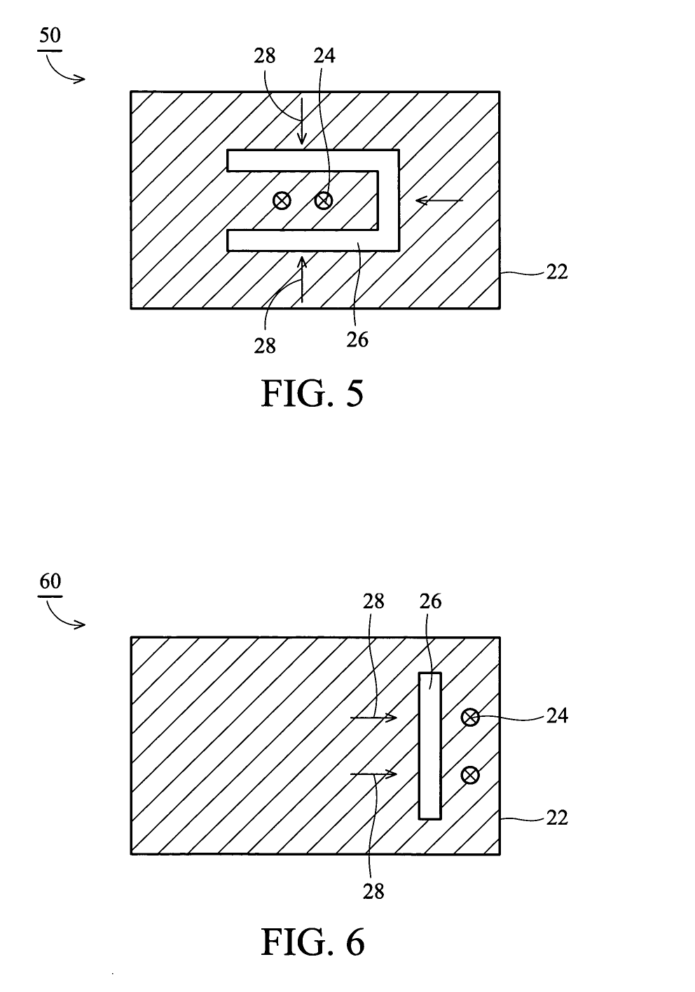

A partial plan layout of the second embodiment of a wiring structure 50 is shown in FIG. 5. In FIG. 5, the dummy dielectric layer 26 comprises a U-shaped profile. The vertical connection 24 corresponds to an interior of the U-shaped profile, thereby efficiently preventing mobile metal atoms and/or defects, shown by arrows 28, generated through stress migration from moving into the vertical connection 24 when the wiring structure 50 is subjected to a rapid temperature change. Since formation of the wiring structure 50 of the second embodiment is similar to the first embodiment, description of detailed formation thereof is omitted here.

### Third Embodiment

A partial plan layout of the third embodiment of a wiring structure 60 is shown in FIG. 6. In FIG. 6, the dummy dielectric layer 26 is a straight line located in the peripheral region of the conductive layer 22. The vertical connection 24 corresponds to a region between an edge of the conductive layer 22 and the dummy dielectric layer 26, thereby efficiently preventing mobile metal atoms and/or defects, shown by arrows 28, generated through stress migration from moving into the vertical connection 24 when the wiring structure 60 is subjected to a rapid temperature change. Since formation of the wiring structure 60 of the second embodiment is similar to the first embodiment, description of detailed formation thereof is omitted here.

The embodiments provide wire structures for use in semiconductor devices with improved reliability. A conductive layer electrically connected to at least one vertical connection formed in an insulating layer is provided. A dummy dielectric layer is formed in a portion of the conductive layer. The dummy dielectric layer is located in a region adjacent to (near or around) the vertical connection. Thus, the dummy dielectric layer prevents mobile metal atoms and/or defects generated through stress migration from moving into the vertical connection when the wiring structure is subjected to a rapid temperature change, thereby eliminating via failure and improving reliability.

While the invention has been described by way of example and in terms of preferred embodiment, it is to be understood that the invention is not limited thereto. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A semiconductor device, comprising:
a conductive layer electrically connected to at least one vertical connection formed in an insulating layer; and
a dummy dielectric layer formed in a portion of the conductive layer;
wherein the dummy dielectric layer is located in a region adjacent to the vertical connection.

2. The semiconductor device according to claim 1, wherein the conductive layer comprises copper, aluminum or tungsten.

3. The semiconductor device according to claim 1, wherein the vertical connection comprises copper aluminum or tungsten.

4. The semiconductor device according to claim 1, wherein the dummy dielectric layer comprises a low-k material.

5. The semiconductor device according to claim 1, wherein the dummy dielectric layer comprises two parallel segments, and the vertical connection corresponds to a region between the two parallel segments.

6. The semiconductor device according to claim 1, wherein the dummy dielectric layer comprises a U-shaped profile, and the vertical connection corresponds to an interior of the U-shaped profile.

7. The semiconductor device according to claim 1, wherein the dummy dielectric layer is a straight line located in a peripheral region of the conductive layer, and the vertical connection corresponds to a region between an edge of the conductive layer and the dummy dielectric layer.

8. The semiconductor device according to claim 1, wherein a width of the dummy dielectric layer is between about 0.5 μm and 10 μm.

9. The semiconductor device according to claim 1, wherein a spacing between the vertical connection and the dummy dielectric layer is between about 0 μm and 2 μm.

10. A wiring structure, comprising:
a metal layer electrically connected to at least one vertical connection formed in an insulating layer; and
a dummy dielectric layer formed in a portion of the metal layer;
wherein the dummy dielectric layer is located in a region adjacent to the vertical connection to prevent mobile metal atoms and/or defects generated through stress migration from moving into the vertical connection.

11. The structure according to claim 10, wherein the metal layer comprises copper, aluminum or tungsten.

12. The structure according to claim 10, wherein the vertical connection comprises copper, aluminum or tungsten.

13. The structure according to claim 10, wherein the dummy dielectric layer comprises a low-k material.

14. The structure according to claim 10, wherein the dummy dielectric layer comprises two parallel segments, and the vertical connection corresponds to a region between the two parallel segments.

15. The structure according to claim 10, wherein the dummy dielectric layer comprises a U-shaped profile, and the vertical connection corresponds to an interior of the U-shaped profile.

16. The structure according to claim 10, wherein the dummy dielectric layer is a straight line located in a peripheral region of the metal layer, and the vertical connection corresponds to a region between an edge of the metal layer and the dummy dielectric layer.

17. The structure according to claim 10, wherein a width of the dummy dielectric layer is between about 0.5 μm and 10 μm.

18. The structure according to claim 10, wherein a spacing between the vertical connection and the dummy dielectric layer is between about 0 μm and 2 μm.

19. A method of forming a semiconductor device, comprising:
providing a substrate comprising a wiring thereabove;
forming a dielectric layer above the wiring and the substrate;
forming at least one hole exposing the wiring in the dielectric layer;
forming a trench in the dielectric layer, thereby leaving a dummy dielectric layer on a top of the dielectric layer;
forming a vertical connection in the hole; and
forming a conductive layer electrically connected to the vertical connection in the trench;
wherein the dummy dielectric layer is located in a portion of the conductive layer and a region adjacent to the vertical connection.

20. The method according to claim 19, wherein the conductive layer comprises copper, aluminum or tungsten.

21. The method according to claim 19, wherein the vertical connection comprises copper, aluminum or tungsten.

22. The method according to claim 19, wherein the dummy dielectric layer comprises a low-k material.

23. The method according to claim 19, wherein the dummy dielectric layer comprises two parallel segments, and the vertical connection corresponds to a region between the two parallel segments.

24. The method according to claim 19, wherein the dummy dielectric layer comprises a U-shaped profile, and the vertical connection corresponds to an interior of the U-shaped profile.

25. The method according to claim 19, wherein the dummy dielectric layer is a straight line located in a peripheral region of the conductive layer, and the vertical connection corresponds to a region between an edge of the conductive layer and the dummy dielectric layer.

26. The method according to claim 19, wherein a width of the dummy dielectric layer is between about 0.5 μm and 10 μm.

27. The method according to claim 19, wherein a spacing between the vertical connection and the dummy dielectric layer is between about 0 μm and 2 μm.

28. A method of forming a semiconductor device, comprising:
forming a conductive layer comprising at least one opening above a substrate;
forming a dummy dielectric layer in the opening;
forming an intermetal dielectric layer above the conductive layer and the substrate; and
forming a vertical connection electrically connected to the conductive layer in the intermetal dielectric layer;
wherein the dummy dielectric layer is located in a portion of the conductive layer and a region adjacent to the vertical connection.

29. The method according to claim 28, wherein the conductive layer comprises copper, aluminum or tungsten.

30. The method according to claim 28, wherein the vertical connection comprises copper, aluminum or tungsten.

31. The method according to claim 28, wherein the dummy dielectric layer and the intermetal dielectric layer comprise the same material.

32. The method according to claim 28, wherein the dummy dielectric layer and the intermetal dielectric layer comprise different materials.

33. The method according to claim 28, wherein the dummy dielectric layer comprises two parallel segments, and the vertical connection corresponds to a region between the two parallel segments.

34. The method according to claim 28, wherein the dummy dielectric layer comprises a U-shaped profile, and the vertical connection corresponds to an interior of the U-shaped profile.

35. The method according to claim 28, wherein the dummy dielectric layer is a straight line located in a peripheral region of the conductive layer, and the vertical connection corresponds to a region between an edge of the conductive layer and the dummy dielectric layer.

36. The method according to claim 28, wherein a width of the dummy dielectric layer is between about 0.5 μm and 10 μm.

37. The method according to claim 28, wherein a spacing between the vertical connection and the dummy dielectric layer is between about 0 μm and 2 μm.
